(19) United States
(12) Patent Application Publication
(10) Pub. No.: US 2016/0233873 A1
(43) Pub. Date: Aug. 11, 2016

(54) DEVICE AND METHOD FOR CONVERTING ANALOG INFORMATION

(71) Applicant: Huawei Technologies Co., Ltd., Shenzhen (CN)

(72) Inventors: Kinnang LAU, Hong Kong (CN); Wei HAN, Hong Kong (CN); Feibai ZHU, Hong Kong (CN); Xiangming KONG, Shenzhen (CN)

(21) Appl. No.: 15/131,959

(22) Filed: Apr. 18, 2016

Related U.S. Application Data
(63) Continuation of application No. PCT/CN2013/085494, filed on Oct. 18, 2013.

(51) Int. Cl. H03M 1/06; H03M 1/12; H03M 7/30

(52) U.S. Cl. CPC H03M 1/0626; H03M 7/3062; H03M 1/1245

(57) ABSTRACT

Embodiments of the present invention provide a device and a method for converting analog information, which achieve sufficient information spread of a sparse signal with a filter of relative low order and reduce hardware complexity, and which is not only applicable to processing of time domain sparse signals, but also applicable to processing of frequency domain signals. The method includes: multiplying an analog sparse signal with a random sequence to obtain a randomized analog sparse signal; performing IIR filtering to the randomized analog sparse signal to obtain an information spread random analog sparse signal; reducing a frequency of the information spread random sparse signal to obtain a frequency-reduced random analog sparse signal; and sampling the frequency-reduced random analog sparse signal with a low sampling rate to obtain a compressed sampled signal.

### CROSS-REFERENCE TO RELATED APPLICATIONS

This application is a continuation of International Patent Application No. PCT/CN2013/085494, filed on Oct. 18, 2013, which is hereby incorporated by reference in its entirety.

### TECHNICAL FIELD

The present invention relates to the field of signal processing and, in particular, to a device and a method for converting analog information.

### BACKGROUND

Compressed sensing technology brings key breakthrough to signal acquisition technology, which can sample sparse signals with a sampling rate much lower than Nyquist sampling rate and can reconstruct original sparse signals using the sampled signals.

Currently, the latest technique in the field is to perform convolution on a sparse signal with a random finite impulse response (Random Finite Impulse Response, R-FIR), so that the information of the sparse signal can be spread over the sampling points and then be processed by a sampling rate reducing structure to enable the processed signal to be sampled by an analog-digital converter with low sampling rate.

The inventor of the present invention found that at least the following problems exist in the current R-FIR method:

The filter implementing R-FIR needs to have relative high order to achieve sufficient spread of the information of the time domain sparse signal, and thus the implementation requires more time-delay devices and has higher hardware complexity. Meanwhile, a low-order R-FIR method is only applicable to processing of frequency domain sparse signals, but is not applicable to time domain sparse signals.

### SUMMARY

Embodiments of the present invention provide a device and a method for converting analog information, which achieve sufficient information spread of a sparse signal by using a filter of relative low order and reduce hardware complexity, and which are not only applicable to processing of time domain sparse signals, but also applicable to processing of frequency domain signals.

In order to achieve the above object, the embodiments of the invention are realized by the following technical solutions.

In a first aspect, an embodiment of the present invention provides a device for converting analog information, the device includes a random sequence multiplier, an infinite impulse response (Infinite Impulse Response, IIR) filter, a sampling rate reducing device and a low sampling rate analog-digital converter, where,

the random sequence multiplier is configured to multiply an analog sparse signal with a random sequence to obtain a randomized analog sparse signal;

the IIR filter is configured to perform BR filtering to the randomized analog sparse signal to obtain an information spread random analog sparse signal;

the sampling rate reducing device is configured to reduce a frequency of the information spread random sparse signal to obtain a frequency-reduced random analog sparse signal; and

the low sampling rate analog-digital converter is configured to sample the frequency-reduced random analog sparse signal with a low sampling rate to obtain a compressed sampled signal.

In a first possible implementation, combining the first aspect, the random sequence multiplier includes a random sequence generator and a first multiplier, where,

the random sequence generator is configured to generate a random sequence, where the random sequence includes a random bipolar waveform, where positive and negative polarities of values of the random bipolar waveform conform to any one of Bernoulli distribution, Gaussian distribution and sub-Gaussian distribution; and

the first multiplier is configured to multiply the random sequence with the analog sparse signal to obtain the randomized analog sparse signal.

In a second possible implementation, combining the first aspect or the first possible implementation, the IIR filter includes any one of the following:

a single-stage IIR filter; or,

a cascade form IIR filter; or,

a direct form II IIR filter.

In a third possible implementation, combining any one of the first aspect, and the first and the second possible implementations, all coefficients in the IIR filter are independently and identically distributed random coefficients.

In a fourth possible implementation, combining any one of the first aspect, and the first, the second and the third possible implementations, the sampling rate reducing device is an integrator or a low-pass filter.

In a second aspect, an embodiment of the present invention provides a method for converting analog information, including:

multiplying an analog sparse signal with a random sequence to obtain a randomized analog sparse signal;

performing IIR filtering to the randomized analog sparse signal to obtain an information spread random analog sparse signal;

reducing a frequency of the information spread random sparse signal to obtain a frequency-reduced random analog sparse signal; and

sampling the frequency-reduced random analog sparse signal with a low sampling rate to obtain a compressed sampled signal.

In a first possible implementation, combining the second aspect, the random sequence includes a random bipolar waveform, where positive and negative polarities of values of the random bipolar waveform conform to any one of Bernoulli distribution, Gaussian distribution and sub-Gaussian distribution.

In a second possible implementation, combining the second aspect or the first possible implementation, the performing IIR filtering to the randomized analog sparse signal includes any one of the following:

performing IIR filtering to the randomized analog sparse signal by using a single-stage IIR filter; or

performing IIR filtering to the randomized analog sparse signal by using a cascade form IIR filter; or

performing IIR filtering to the randomized analog sparse signal by using a direct form II IIR filter.

In a third possible implementation, combining any one of the second aspect, and the first and the second possible implementations, all coefficients in the IIR filter are independently and identically distributed random coefficients.

In a fourth possible implementation, combining any one of the first aspect, and the first, the second and the third possible implementations, the reducing the frequency of the information spread random sparse signal, includes:

reducing the frequency of the information spread random sparse signal by using an integrator; or

reducing the frequency of the information spread random sparse signal by using a low-pass filter.

Embodiments of the present invention provide a device and a method for converting analog information, where a analog sparse signal is filtered by an IIR filter so that the information of the analog sparse signal can be spread over the sampling points, thereby achieving sufficient spread of the information of the sparse signal with a filter of relative low order and reducing hardware complexity; in addition, the device and method provided by embodiments of the present invention are not only applicable to processing of frequency domain sparse signals, but also applicable to processing of time domain sparse signals.

### BRIEF DESCRIPTION OF DRAWINGS

To illustrate the technical solutions according to the embodiments of the present invention or in the prior art more clearly, the accompanying drawings required for describing the embodiments or the prior art are introduced below briefly. Apparently, the accompanying drawings in the following descriptions are only some embodiments of the present invention, and persons of ordinary skill in the art can obtain other drawings according to the accompanying drawings without creative efforts.

FIG. 1 is a schematic diagram of a device for converting analog information according to an embodiment of the present invention;

FIG. 2 is a schematic diagram of a device for converting analog information according to a first embodiment of the present invention;

FIG. 3 is a schematic diagram of a device for converting analog information according to a second embodiment of the present invention;

FIG. 4 is a performance comparison chart between conversion of time domain sparse signal by the device for converting analog information according to the second embodiment of the present invention and the prior art;

FIG. 5 is a performance comparison chart between conversion of frequency domain sparse signal by the device for converting analog information according to the second embodiment of the present invention and the prior art;

FIG. 6 is a schematic diagram of a device for converting analog information according to a third embodiment of the present invention;

FIG. 7 is a schematic flow chart of a method for converting analog information according to an embodiment of the present invention;

FIG. 8A is a time domain diagram of a frequency domain sparse signal according to an embodiment of the present invention;

FIG. 8B is a frequency domain diagram of a frequency domain sparse signal according to an embodiment of the present invention;

FIG. 9A is a time domain diagram of a random sequence according to an embodiment of the present invention;

FIG. 9B is a frequency domain diagram of a random sequence according to an embodiment of the present invention;

FIG. 9C is a local frequency domain diagram of a random sequence according to an embodiment of the present invention;

FIG. 9D is a local frequency domain diagram of a random sequence according to an embodiment of the present invention;

FIG. 10A is a time domain diagram of a randomized analog sparse signal according to an embodiment of the present invention;

FIG. 10B is a frequency domain diagram of a randomized analog sparse signal according to an embodiment of the present invention;

FIG. 11A is a time domain diagram of a signal after passing through an IIR filter according to an embodiment of the present invention;

FIG. 11B is a frequency domain diagram of a signal after passing through an IIR filter according to an embodiment of the present invention;

FIG. 12 is a frequency domain diagram of a frequency-reduced random analog sparse signal according to an embodiment of the present invention.

### DESCRIPTION OF EMBODIMENTS

The technical solutions in the embodiments of the present invention will be described clearly and completely with reference to accompanying drawings in the embodiments of the present invention. Obviously, the embodiments described are only part of the embodiments provided by the present invention, but not all of them. All other embodiments, which can be derived by persons skilled in the art from the embodiments given herein without creative work, shall fall within the protection scope of the present invention.

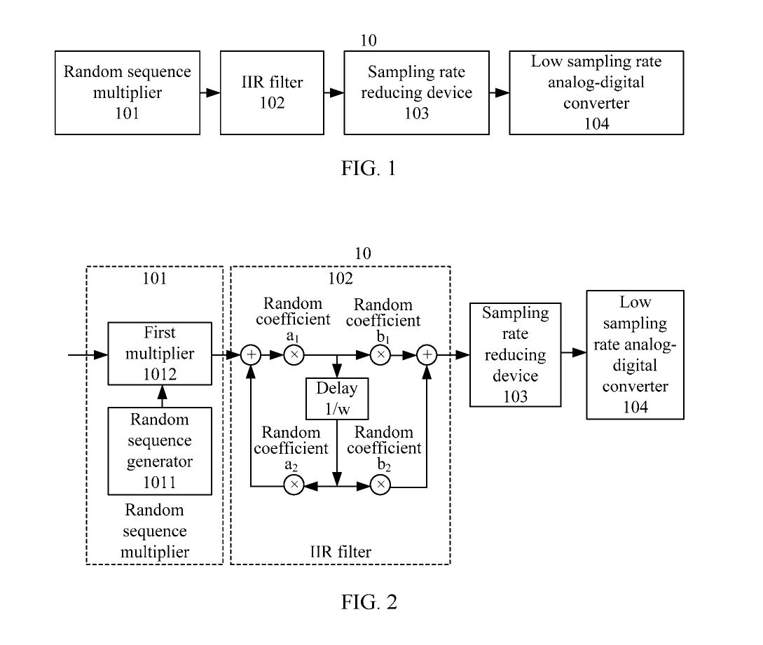

An embodiment of the present invention provides a device 10 for converting analog information, as shown in FIG. 1, including a random sequence multiplier 101, an IIR filter 102, a sampling rate reducing device 103 and a low sampling rate analog-digital converter 104 which are connected in sequence, in which:

The random sequence multiplier 101 is configured to multiply an analog sparse signal with a random sequence to obtain a randomized analog sparse signal.

Illustratively, as shown in FIG. 2, the random sequence multiplier 101 includes a random sequence generator 1011 and a first multiplier 1012, in which:

The random sequence generator 1011 is configured to generate a random sequence, the random sequence includes: a random bipolar waveform, the positive and negative polarities of the values of the random bipolar waveform can conform to but not limited to Bernoulli distribution (Bernoulli Distribution), Gaussian distribution (Gaussian Distribution) or sub-Gaussian distribution (Sub-Gaussian Distribution) etc; preferably, the embodiment of the present invention adopts a random bipolar waveform as the random sequence, where the positive and negative polarities of values of the random sequence conform to Bernoulli distribution.

The first multiplier 1012 is configured to multiply the random sequence with the analog sparse signal to obtain the randomized analog sparse signal, where the multiplying of the random sequence with the analog sparse signal, i.e. modulating the analog sparse signal by the random sequence, is equivalent to calculating convolution of the spectrum of the random sequence and the spectrum of the analog sparse signal in frequency domain, where the spectrum of the random sequence has frequency points of the random sequence over a range from low frequency to high frequency in frequency domain, and, then, according to a property of convolution calculation, the spectrum of the analog sparse signal will be shifted to the frequency points of the random sequence in the range from low frequency to high frequency, so as to achieve spectrum shifting of the analog sparse signal.

The IIR filter 102 is configured to perform IIR filtering to the randomized analog sparse signal to obtain an information spread random analog sparse signal.

Illustratively, the IIR filter 102 may include any one of the following:

a single-stage IIR filter; or,

a cascade form IIR filter; or,

a direct form II IIR filter.

Preferably, all coefficients in the IIR filter are independently and identically distributed random coefficients.

The sampling rate reducing device 103 is configured to reduce the frequency of the information spread random analog sparse signal to obtain the frequency-reduced random analog sparse signal. Compared with the original analog sparse signal, in frequency domain, the spectrum range of the frequency-reduced random analog sparse signal obtained by the sampling rate reducing device 103 falls into a low frequency region near zero frequency, and thus it can be known according to Nyquist sampling theorem that since the spectrum range of the frequency-reduced random analog sparse signal falls into the low frequency region, the sampling rate for the frequency-reduced random analog sparse signal may also be reduced, so that further processing can be performed by a low sampling rate working device, and there is no need for a high sampling rate working device, thereby reducing hardware complexity.

Illustratively, the sampling rate reducing device 103 can be but not limited to an integrator or a low-pass filter, which will not be limited in the embodiment of the present invention. Preferably, the embodiment of the present invention selects an integrator as the sampling rate reducing device 103.

The low sampling rate analog-digital converter 104 is configured to sample, with a low sampling rate, the above frequency-reduced random analog sparse signal to obtain a compressed sampled signal, where the low sampling rate analog-digital converter 104 may be an analog-digital converter with a uniform sampling structure or an analog-digital converter with a non-uniform sampling structure, which will not be limited in the embodiment of the present invention. Preferably, the present embodiment selects an analog-digital converter with a uniform sampling structure as the low sampling rate analog-digital converter 104.

The present embodiment provides a device 10 for converting analog information, through filtering the analog sparse signal by an IIR filter, the information of the analog sparse signal can be spread over the sampling points, thereby achieving sufficient spread of the information of the sparse signal with a filter of relative low order and reducing hardware complexity; in addition, the device and method provided by embodiments of the present invention are not only applicable to processing of time domain sparse signals, but also applicable to processing of frequency domain sparse signals.

The above device 10 for converting analog information will be illustrated through the following embodiments.

### Embodiment 1

As shown in FIG. 2, the present embodiment provides a device 10 for converting analog signal, including a random sequence multiplier 101, an IIR filter 102, a sampling rate reducing device 103 and a low sampling rate analog-digital converter 104, which are connected in sequence.

The random sequence multiplier 101, the sampling rate reducing device 103 and the low sampling rate analog-digital converter 104 in the present embodiment have the same functions as in the previous embodiment, which will not be repeated here. In the present embodiment, the IIR filter 102 can be composed of one or more single-stage IIR filters as shown in FIG. 2. In the present embodiment, the signal processing procedure of the single-stage IIR filter is as described by BR filter 102 in FIG. 2, where the randomized analog sparse signal obtained by the random sequence multiplier 101 is added with a feedback signal which is a unit-delayed version of the randomized analog sparse signal. In FIG. 2, unit delay may be represented by 1/w, and it can be understood that, 1/w represents the pulse width of the signal generated by the clock, and when the clock generates a signal with a delay of one pulse width, the signal is delayed by a unit.

Then the signal obtained after the addition is added with a feedforward signal which is a unit-delayed version of the randomized analog sparse signal, to obtain an information spread random analog sparse signal after the processing of the IIR filter. Preferably, during passing each data path of the IIR filter 102, the randomized analog sparse signal is multiplied with a random coefficient via a multiplier, so as to achieve robustness under different sparsities. Furthermore, all the random coefficients of the IIR filter 102 are independently and identically distributed, and thus, the IIR filter in the present embodiment is an R-IIR filter.

The present embodiment provide a device 10 for converting analog information, through filtering the analog sparse signal by a R-IIR filter, the information of the analog sparse signal can be spread over the sampling points, thereby achieving sufficient spread of the information of the sparse signal with a filter of relative low filter order and reducing hardware complexity; in addition, the device and method provided by embodiments of the present invention are not only applicable to processing of time domain sparse signals, but also applicable to processing of frequency domain sparse signals.

### Embodiment 2

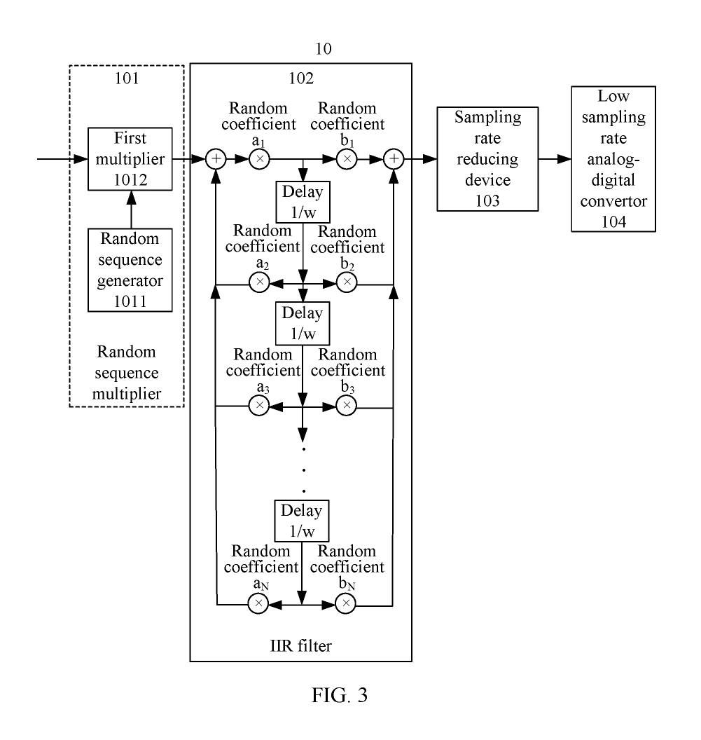

As shown in FIG. 3, the present embodiment provides a device 10 for converting analog signal, including a random sequence multiplier 101, an IIR filter 102, a sampling rate reducing device 103 and a low sampling rate analog-digital converter 104 which are connected in sequence.

The random sequence multiplier 101, the sampling rate reducing device 103 and the low sampling rate analog-digital converter 104 in the present embodiment have the same functions as in the previous embodiments, which will not be repeated here. In the present embodiment, as can be understood by those skilled in the art, during signal processing procedure of the IIR filter, at least one single-stage IIR filter as shown in FIG. 2 is needed for processing a signal. Here, the number of single-stage IIR filter may also be referred to as order.

In the present embodiment, the IIR filter 102 can be a direct form II IIR filter composed of multiple single-stage filters, as shown in FIG. 3. Set the IIR filter 102 as an Nth-order IIR filter, those skilled in the art can understand that, when N=1, the present embodiment is identical to Embodiment 1. Similar to Embodiment 1, all the random coefficients of the IIR filter 102 are independently and identically distributed, and thus the IIR filter 102 in the present embodiment is an R-IIR filter.

In the embodiment of the present invention, the technical advantages of the converting device 10 can be obtained by comparing the device 10 for converting analog information with the device for implementing an R-FIR method in the prior art.

Optionally, the present embodiment selects time domain sparse signals as the analog sparse signal, the sparsity of which are 10%, 12%, 14%, 16%, 18% and 20%, respectively, where the sparsity of a time domain sparse signal represents a ratio of non-zero time length of the time domain sparse signal to the whole time length of the signal, and during specific implementation. The sparsity of the time domain sparse signal can be set or adjusted according to needs.

First, these time domain sparse signals are input, as input signals, into the converting device 10 of the present embodiment, a 3-order R-FIR device and a 139-order R-FIR device for analog conversion, where the order of the R-IIR filter for the converting device 10 of the present embodiment is 3.

Then, reconstruction is performed with the analog converted signals obtained after the analog conversion of the above three devices, to obtain reconstructed signals. The embodiment of the present invention does not limit the reconstruction algorithm, which is preferably an iteration hard threshold algorithm.

Finally, the reconstructed signals are compared with the original input signal, to determine whether the reconstructed signals can accurately describe the original input signal. Specifically, if a reconstructed signal and the original input signal only have differences in signal amplitude and constant delay, then it is determined that the reconstructed signal can accurately describe the original input signal.

Preferably, the present embodiment calculates the accuracy of the reconstructed signal using Monte Carlo method. Specifically, a selected time domain sparse signal is input, as an input signal, into the above three devices M times, respectively, where M is preset and M ranges from 500 to 2000, and thus M analog converted signals can be obtained for each time domain sparse signal; then reconstruction is performed with the M analog converted signals of each time domain sparse signal, to obtain M reconstructed signals corresponding to each time domain sparse signal; and, finally, the number of reconstructed signals which can accurately describe the corresponding input signal, in the M reconstructed signals of each time domain sparse signal is determined, thereby acquiring the accuracy of the reconstructed signals of each time domain sparse signal.

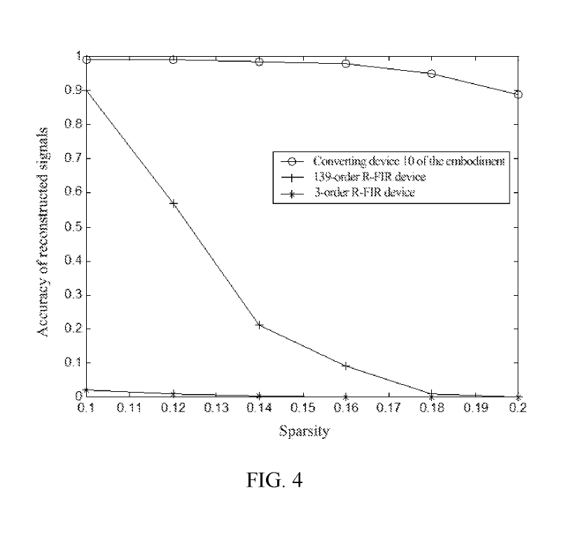

The result is as shown in FIG. 4. We can see from the figure that the accuracy of the signals, which are reconstructed after the converting device 10 provided by the present embodiment performs analog information conversion on the time domain sparse signal, is much higher than that for the R-FIR device which is also of 3 order, and is also higher than that for the 139-order R-FIR device, and thus we can see that, the converting device 10 including a 3-order R-FIR filter provided by the present embodiment only needs three time-delay components, however, for the R-FIR device which also uses three time-delay components, the input signal could hardly be reconstructed, and the reconstruction performance of the high order R-FIR device is also much lower than the converting device 10 including a 3-order R-FIR filter provided by the present embodiment. Therefore, it can be seen that the converting device 10 including a 3-order R-FIR filter provided by the present embodiment not only performs better in analog conversion of a time domain sparse signal than the R-FIR device, but also reduces hardware complexity.

Optionally, the present embodiment selects frequency domain sparse signals as the analog sparse signal, the sparsity of these frequency domain sparse signals are 10%, 20%, 30%, 40% and 50%, respectively, where the sparsity of a frequency domain sparse signal represents the ratio of non-zero spectrum bandwidth in the frequency domain sparse signal to the whole bandwidth length of the signal.

First, these frequency domain sparse signals are input, as input signals, into the converting device 10 of the present embodiment and a 1-order R-FIR device for analog conversion, where the order of the R-IIR filter for the converting device 10 of the present embodiment is also 1.

Then, reconstruction is performed with the analog converted signals obtained after the analog conversion of the above two devices, to obtain reconstructed signals. The embodiment of the present invention does not limit the reconstruction algorithm, which is preferably an iteration hard threshold algorithm.

Finally, the reconstructed signals are compared with the original input signal, to determine whether the reconstructed signals can accurately describe the original input signal. Specifically, if a reconstructed signal and the original input signal only have differences in signal amplitude and constant delay, then it is determined that the reconstructed signal can accurately describe the original input signal.

Preferably, the present embodiment calculates the accuracy of the reconstructed signal using Monte Carlo method. Specifically, a selected frequency domain sparse signal is input, as an input signal, into the above three devices M times, respectively, where M is preset and M ranges from 500 to 2000, and thus M analog converted signals can be obtained for each frequency domain sparse signal; then reconstruction is performed using the M analog converted signals of each frequency domain sparse signal, to obtain M reconstructed signals corresponding to each frequency domain sparse signal; and, finally, the number of reconstructed signals which can accurately describe the corresponding input signals, in the M reconstructed signals of each frequency domain sparse signal is determined, thereby acquiring the accuracy of the reconstructed signals of each frequency domain sparse signal.

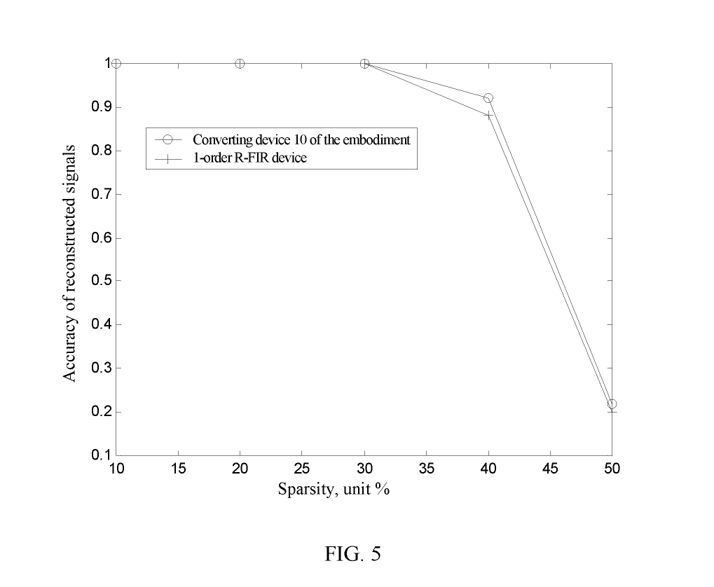

The result is as shown in FIG. 5. We can see from the figure that the accuracy of the signals which are reconstructed after the converting device 10 provided by the present embodiment performs analog information conversion on the frequency domain sparse signal, is better in performance than the 1-order R-FIR device, and thus we can see that, for the converting device 10 including a 1-order R-IIR filter provided by the present embodiment, the accuracy of the signals reconstructed after it performs analog information conversion on the frequency domain sparse signal, is higher than that for the 1-order R-FIR device, while, from the embodiment of FIG. 4, it can be known that the converting device 10 of the R-IIR filter provided by the present embodiment is applicable to more types of sparse signals compared with R-FIR devices.

The present embodiment provides a device 10 for converting analog information, through filtering the analog sparse signal by a R-IIR filter, the information of the analog sparse signal can be spread over the sampling points, thereby achieving sufficient spread of the information of the sparse signal with a filter of relative low order and reducing hardware complexity; in addition, the device and method provided by embodiments of the present invention are not only applicable to processing of time domain sparse signals, but also applicable to processing of frequency domain sparse signals.

### Embodiment 3

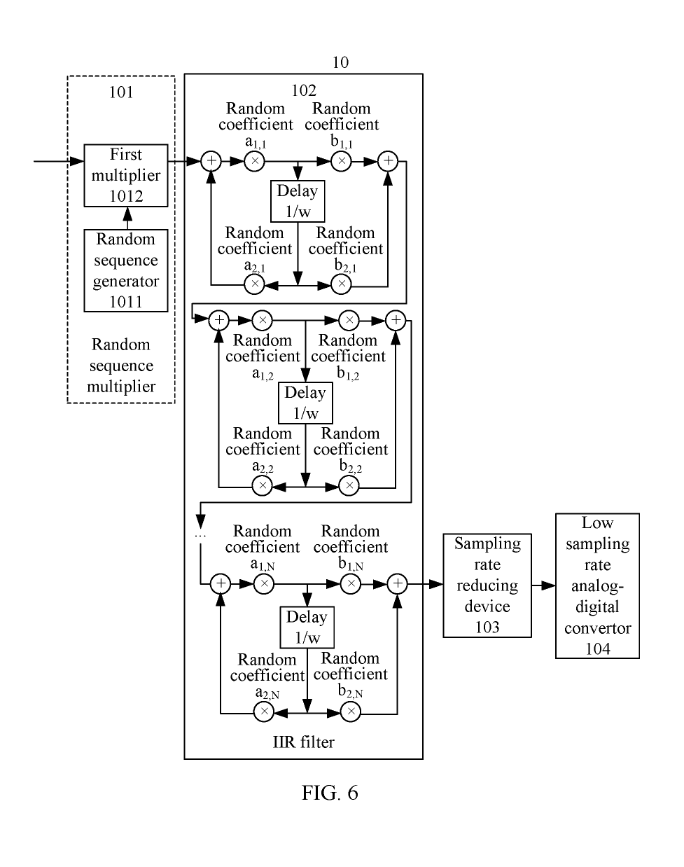

As shown in FIG. 6, the present embodiment provides a device 10 for converting analog signal, including a random sequence multiplier 101, an IIR filter 102, a sampling rate reducing device 103 and a low sampling rate analog-digital converter 104 which are connected in sequence.

The random sequence multiplier 101, the sampling rate reducing device 103 and the low sampling rate analog-digital converter 104 in the present embodiment have the same functions as in the previous embodiment, which will not be repeated here. In the present embodiment, as can be understood by those skilled in the art, during signal processing procedure of the IIR filter, at least one single-stage IIR filter as shown in FIG. 2 is needed for processing a signal. Here, the number of single-stage IIR filter may also be referred to as order.

In the present embodiment, the IIR filter 102 may be a cascade form IIR filter composed of multiple single-stage filters, as shown in FIG. 6. Set the IIR filter 102 as an Nth-order IIR filter, those skilled in the art can understand that, when N=1, the present embodiment is identical to Embodiment 1. Similar to Embodiment 1, all the random coefficients of the BR filter 102 are independently and identically distributed, and thus the BR filter 102 in the present embodiment is an R-IIR filter.

Those skilled in the art can understand, the cascade form BR filter can be equivalent to a direct form II IIR filter of the same order through coefficient conversion, therefore, similar to Embodiment 2, the converting device including a cascade form IIR filter provided by the present embodiment can also perform analog conversion to time domain sparse signals and frequency domain sparse signals and achieve the same performance as in Embodiment 2, and the specific process is as shown in Embodiment 2, which will not be repeated here.

The present embodiment provide a device 10 for converting analog information, through filtering the analog sparse signal by a R-IIR filter, the information of the analog sparse signal can be spread over the sampling points, thereby achieving sufficient spread of the information of the sparse signal with a filter of relative low order and reducing hardware complexity; in addition, the device and method provided by embodiments of the present invention are not only applicable to processing of time domain sparse signals, but also applicable to processing of frequency domain sparse signals.

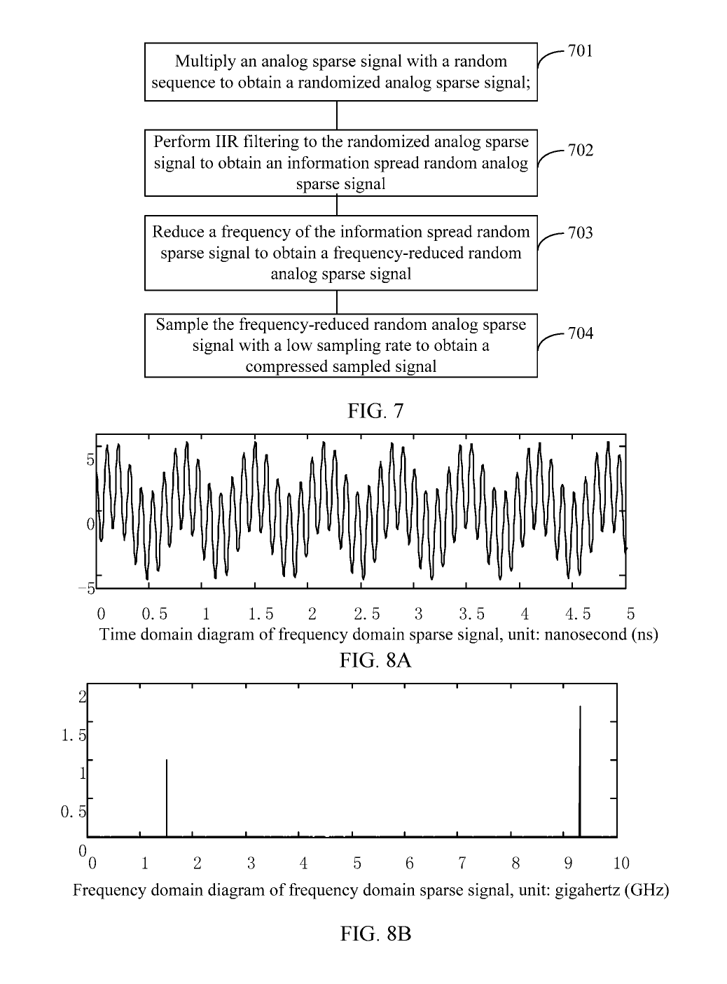

An embodiment of the present invention provides a method for converting analog information, as shown in FIG. 7, including:

S701: multiply an analog sparse signal with a random sequence to obtain a randomized analog sparse signal.

Illustratively, the random sequence includes: a random bipolar waveform, where the positive and negative polarities of values of the random bipolar waveform may conform to but not limited to Bernoulli distribution, Gaussian distribution or sub-Gaussian distribution etc.

Specifically, in the present embodiment, the multiplication of the random sequence and the analog sparse signal can be implemented by a high speed multiplier.

Preferably, the embodiment of the present invention adopts a random bipolar waveform as the random sequence, where the positive and negative polarities of values of the random sequence conform to Bernoulli distribution.

In addition, in the present embodiment, the analog sparse signal may be a time domain sparse signal, and may also be a frequency domain sparse signal, but is not limited to the above two kinds of sparse signals, which will not be further illustrated.

Illustratively, in the present embodiment, the frequency domain sparse signal is as shown in FIG. 8, in which figure A is a time domain waveform of the signal, where the horizontal axis represents time with a unit of nanosecond (ns), and the vertical axis represents the amplitude of the time domain waveform; figure B is the spectrum diagram in the frequency domain corresponding to the signal, where the horizontal axis represents frequency with a unit of gigahertz (GHz), and the vertical axis represents the amplitude of the signal in frequency domain. It can be seen from figure B of FIG. 8 that, the signal has frequency amplitudes at frequency points 1.5 GHz and 9.3 GHz, and if sampling is performed on the signal as shown in FIG. 8, according to Nyquist sampling theorem, the sampling rate is at least 18.6 GHz, which results in over high sampling rate and increases the complexity of the sampling device.

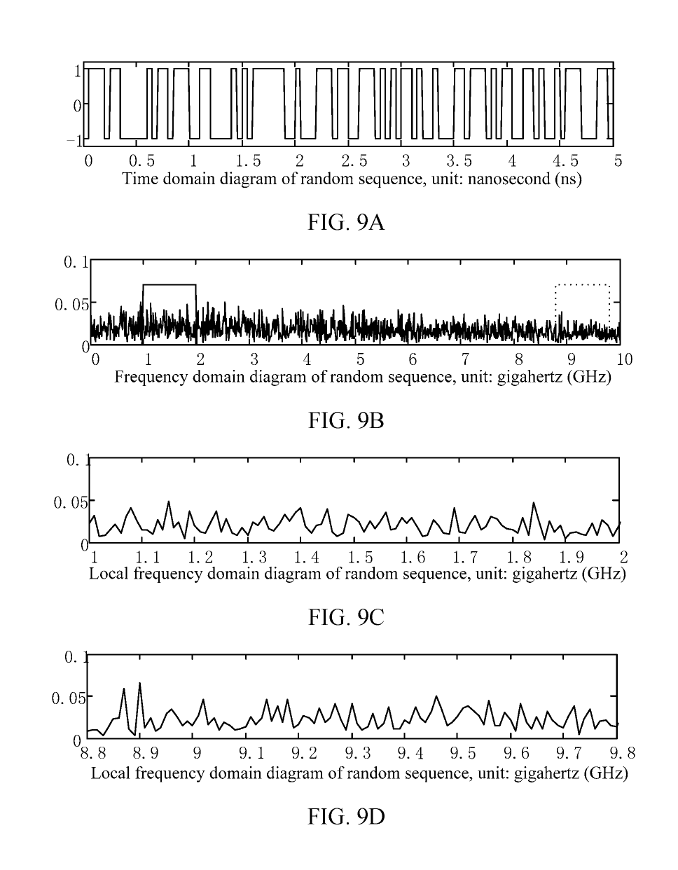

The bipolar random sequence is as shown in FIG. 9, in which figure A is a time domain waveform of the random sequence, where the horizontal axis represents time with a unit of nanosecond (ns), and the vertical axis represents the amplitude of the time domain waveform; figure B in FIG. 9 is the frequency domain diagram corresponding to the random sequence, where the horizontal axis represents frequency with a unit of gigahertz (GHz), and the vertical axis represents the amplitude of the signal in frequency domain. It can be seen that, the amplitude of the signal in the whole frequency domain from zero frequency to high frequency (10 GHz) is non-zero, for the details, please refer to the frequency domain diagram of the low frequency (1 GHz-2 GHz) region shown in figure C of FIG. 9 and the frequency domain diagram of the high frequency (9 GHz-10 GHz) region shown in figure D of FIG. 9.

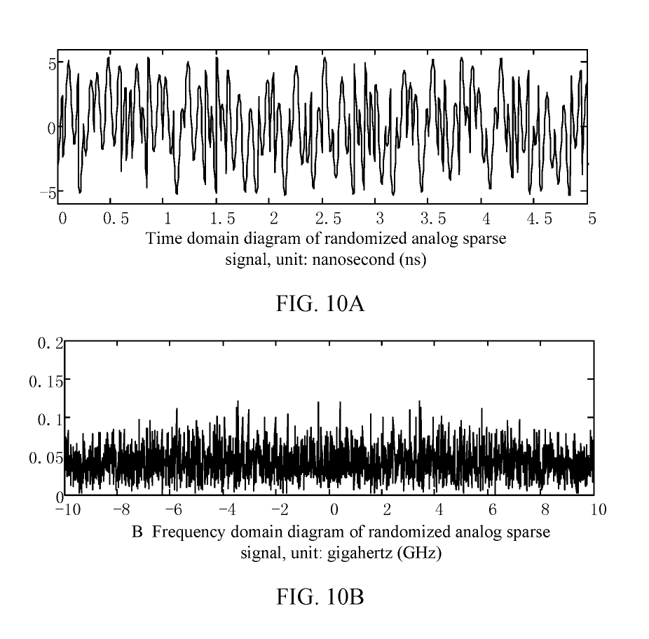

When multiplying the signal as shown in FIG. 8 with the random sequence as shown in FIG. 9 in time domain, a randomized analog sparse signal as shown in FIG. 10 can be obtained, where figure A of FIG. 10 is the time domain diagram of the randomized analog sparse signal and figure B of FIG. 10 is the frequency domain diagram thereof, the coordinate axes of the time domain waveform and the coordinate axes in the spectrum diagram are the same as previously illustrated, which will not be repeated here. It can be seen that, after the multiplication, the spectrum of the frequency domain sparse signal is shifted, which is spread over the whole frequency domain region from low frequency to high frequency.

S702: perform IIR filtering to the randomized analog sparse signal to obtain an information spread random analog sparse signal.

Illustratively, the performing IIR filtering to the randomized analog sparse signal may include:

performing BR filtering to the randomized analog sparse signal by using a single-stage IIR filter; or

performing IIR filtering to the randomized analog sparse signal by using a cascade form IIR filter; or

performing IIR filtering to the randomized analog sparse signal by using a direct form II IIR filter.

Preferably, all coefficients in the IIR filter are independently and identically distributed random coefficients, and thus the BR filter is preferably an R-IIR filter.

Illustratively, in the present embodiment, the structure of the IIR filter is as described in Embodiment 2, preferably, the BR filter is a 3-order filter, the expression in time domain for describing the system function of the 3-order filter is

$${α}_{0} y ( n ) = {\sum }_{i = 1}^{3} {α}_{i} y ( n - i ) + {\sum }_{j = 0}^{3} {β}_{i} x ( n - j ) ,$$

the corresponding expression of the system

$$H ( Z ) = \frac{{\sum }_{j = 0}^{3} {β}_{i} {Z}^{- j}}{{α}_{0} - {\sum }_{i = 1}^{3} {α}_{i} {Z}^{- i}} ,$$

function in frequency domain is where x(n) is a signal input to the IIR filter, y(n) is the signal obtained after x(n) passes through the IIR filter, correspondingly, x(n−j) represents a signal obtained after x(n) is performed with unit delay for j times, y(n−i) represents a signal obtained after y(n) is performed with unit time-delay for i times, α₀, α₁, α₂, α₃ and β₀, β₁, β₂, β₃ are coefficients of the IIR filter, these coefficients are random and conform to independent and identical distribution, and in the present embodiment, preferably, these coefficients can all conform to uniform distribution from −1 to +1, which can specifically be:

α₀=0.6428,α₁=−0.1106,α₂=0.2309,α₃=0.5839, and

β₀=0.8436,β₁=0.4764,β₂=−0.6475,β₃=−0.1886.

The process of filtering the signal through the IIR filter is to calculate the convolution of the signal and the time domain expression of the system function of the IIR filter in time domain, or multiply the signal with the frequency domain expression of the system function of the IIR filter in frequency domain.

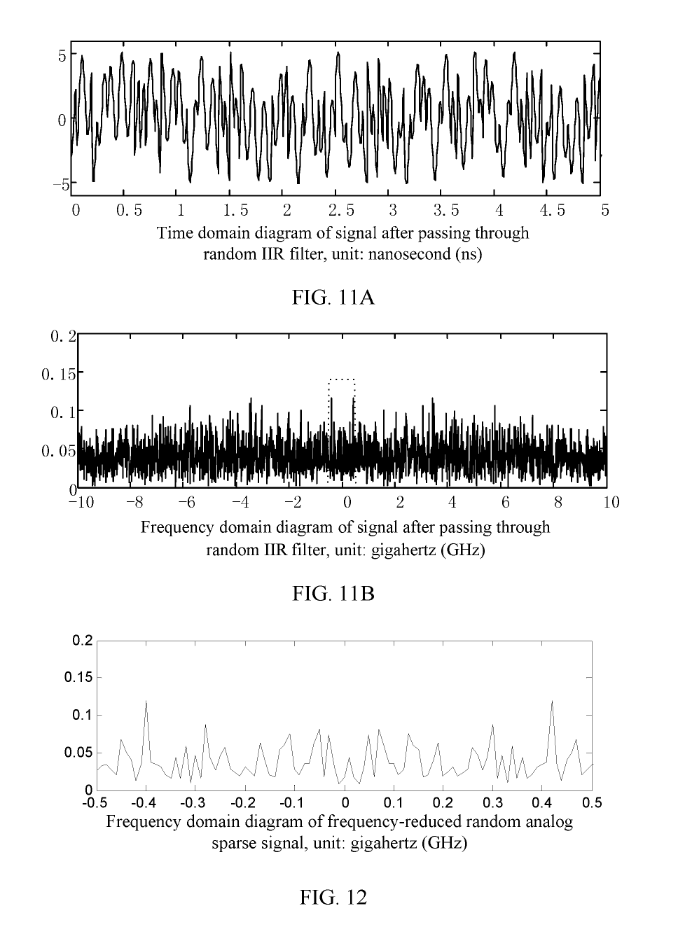

Specifically, in the present embodiment, the filtering of the randomized analog sparse signal as shown in FIG. 10 through an IIR filter can be: performing a convolution operation on the signal as shown in FIG. 10A with the time domain expression of the system function of a 3-order IIR filter, to obtain the time domain diagram as shown in FIG. 11A; or

multiplying the signal as shown in FIG. 10B with the frequency domain expression of the system function of the 3-order IIR filter, to obtain the frequency domain diagram as shown in FIG. 11B; it can be seen that, comparing the signal shown in FIG. 11 with the frequency sparse signal shown in FIG. 8, the signal spectrum shown in FIG. 11 is also spread over the whole frequency domain from low frequency to high frequency.

S703: reduce the frequency of the information spread random sparse signal, to obtain a frequency-reduced random analog sparse signal.

Illustratively, the reducing of the frequency of the information spread random sparse signal can be achieved by a sampling rate reducing device, which includes:

reducing the frequency of the information spread random sparse signal by using an integrator; or

reducing the frequency of the information spread random sparse signal by using a low-pass filter.

Being compared with the original analog sparse signal, the spectrum range of the frequency-reduced random analog sparse signal falls into the low frequency region adjacent near zero frequency, thus it can be known according to Nyquist sampling theorem, since the spectrum range of the frequency-reduced random analog sparse signal falls into the low frequency region, the sampling rate for sampling the frequency-reduced random analog sparse signal is also reduced, so that the further processing can be performed by a low sampling rate working device, and there is no need for a high sampling rate working device, thereby reducing hardware complexity.

Illustratively, as shown in the dotted box in figure B of FIG. 11, in the present embodiment, it is possible to select the portion in the dotted box in FIG. 11B by a low-pass filter, to obtain the frequency-reduced random analog sparse signal as shown in FIG. 12, so as to facilitate further sampling with low sampling rate, where the portion selected by the dotted box as shown in FIG. 11B is the low frequency portion of the signal shown in FIG. 11B, that is, the portion with a frequency range from −0.5 GHz to 0.5 GHz.

S704: sample the frequency-reduced random analog sparse signal with a low sampling rate, to obtain a compressed sampled signal.

Illustratively, in the present embodiment, comparing the signal shown in FIG. 12 with the signal shown in FIG. 8, it can be seen that, when sampling the signal shown in FIG. 12, only a sampling device with a sampling rate of 1 GHz is required, being compared with the sampling device with sampling rate of 18.6 GHz which is required when directly sampling the signal shown in FIG. 8, the sampling rate is significantly reduced, and it can also be understood that the complexity of the sampling device is also reduced.

The present embodiment provide a method for converting analog information, through filtering a analog sparse signal by an IIR filter, the information of the analog sparse signal can be spread over the sampling points, thereby achieving sufficient spread of the information of the sparse signal with a filter of relative low order and reducing hardware complexity; in addition, the device and method provided by embodiments of the present invention are not only applicable to processing of time domain sparse signals, but also applicable to processing of frequency domain sparse signals.

Those of ordinary skill in the art should understand that all or a part of the steps of the method according to the embodiments of the present invention may be implemented through a program instructing relevant hardware. The program may be stored in a computer readable storage medium, when the program is executed, the steps of the above method embodiments are executed. The storage medium comprises various medium that can store the program code, such as ROM, RAM, magnetic disk, or optical disk.

The above descriptions are merely preferred embodiments of the present invention, but not intended to limit the protection scope of the present invention. Any modifications, variations or replacement that can be easily derived by those skilled in the art within the technical scope disclosed by the present invention shall fall within the protection scope of the present invention. Therefore, the protection scope of the present invention is subject to the appended claims.

What is claimed is:

1. A device for converting analog information, wherein the device comprises a random sequence multiplier, an infinite impulse response (IIR) filter, a sampling rate reducing device and a low sampling rate analog-digital converter, wherein,
the random sequence multiplier is configured to multiply an analog sparse signal with a random sequence to obtain a randomized analog sparse signal;
the IIR filter is configured to perform IIR filtering to the randomized analog sparse signal to obtain an information spread random analog sparse signal;
the sampling rate reducing device is configured to reduce a frequency of the information spread random sparse signal to obtain a frequency-reduced random analog sparse signal; and
the low sampling rate analog-digital converter is configured to sample the frequency-reduced random analog sparse signal with a low sampling rate to obtain a compressed sampled signal.

2. The device according to claim 1, wherein the random sequence multiplier comprises a random sequence generator and a first multiplier, wherein,
the random sequence generator is configured to generate a random sequence, wherein the random sequence comprises a random bipolar waveform, wherein positive and negative polarities of values of the random bipolar waveform conform to any one of Bernoulli distribution, Gaussian distribution and sub-Gaussian distribution; and
the first multiplier is configured to multiply the random sequence with the analog sparse signal to obtain the randomized analog sparse signal.

3. The device according to claim 1, wherein the IIR filter comprises any one of following:
a single-stage IIR filter; or,
a cascade form IIR filter; or,
a direct form II IIR filter.

4. The device according to claim 1, wherein all coefficients in the IIR filter are independently and identically distributed random coefficients.

5. The device according to claim 1, wherein the sampling rate reducing device is an integrator or a low-pass filter.

6. The device according to claim 2, wherein the IIR filter comprises any one of following:
a single-stage IIR filter; or,
a cascade form IIR filter; or,
a direct form II IIR filter.

7. The device according to claim 2, wherein all coefficients in the IIR filter are independently and identically distributed random coefficients.

8. The device according to claim 2, wherein the sampling rate reducing device is an integrator or a low-pass filter.

9. The device according to claim 6, wherein all coefficients in the IIR filter are independently and identically distributed random coefficients.

10. The device according to claim 6, wherein the sampling rate reducing device is an integrator or a low-pass filter.

11. A method for converting analog information, comprising:
multiplying an analog sparse signal with a random sequence to obtain a randomized analog sparse signal;
performing infinite impulse response (IIR) filtering to the randomized analog sparse signal to obtain an information spread random analog sparse signal;
reducing a frequency of the information spread random sparse signal to obtain a frequency-reduced random analog sparse signal; and
sampling the frequency-reduced random analog sparse signal with a low sampling rate to obtain a compressed sampled signal.

12. The method according to claim 11, wherein the random sequence comprises a random bipolar waveform, wherein positive and negative polarities of values of the random bipolar waveform conform to any one of Bernoulli distribution, Gaussian distribution and sub-Gaussian distribution.

13. The method according to claim 11, wherein the performing IIR filtering to the randomized analog sparse signal comprises at least one of following:
performing IIR filtering to the randomized analog sparse signal by using a single-stage IIR filter; or
performing IIR filtering to the randomized analog sparse signal by using a cascade form IIR filter; or
performing IIR filtering to the randomized analog sparse signal by using a direct form II IIR filter.

14. The method according to claim 11, wherein all coefficients in the IIR filter are independently and identically distributed random coefficients.

15. The method according to claim 11, wherein the reducing the frequency of the information spread random sparse signal comprises:
reducing the frequency of the information spread random sparse signal by using an integrator; or
reducing the frequency of the information spread random sparse signal by using a low-pass filter.

16. The method according to claim 12, wherein the performing IIR filtering to the randomized analog sparse signal comprises at least one of following:
performing IIR filtering to the randomized analog sparse signal by using a single-stage IIR filter; or
performing BR filtering to the randomized analog sparse signal by using a cascade form IIR filter; or
performing BR filtering to the randomized analog sparse signal by using a direct form II IIR filter.

17. The method according to claim 12, wherein all coefficients in the IIR filter are independently and identically distributed random coefficients.

18. The method according to claim 12, wherein the reducing the frequency of the information spread random sparse signal comprises:
reducing the frequency of the information spread random sparse signal by using an integrator; or
reducing the frequency of the information spread random sparse signal by using a low-pass filter.

19. The method according to claim 16, wherein all coefficients in the IIR filter are independently and identically distributed random coefficients.

20. The method according to claim 16, wherein the reducing the frequency of the information spread random sparse signal comprises:
reducing the frequency of the information spread random sparse signal by using an integrator; or
reducing the frequency of the information spread random sparse signal by using a low-pass filter.
